(19) United States
(12) Patent Application Publication
(10) Pub. No.: US 2025/0120027 A1
(43) Pub. Date: Apr. 10, 2025

(54) EJECTOR HANDLES

(71) Applicant: ITI Engineering, LLC, Winter Springs, FL (US)

(72) Inventor: Gregory L. Atwood, Winter Springs, FL (US)

(73) Assignee: ITI Engineering, LLC, Winter Springs, FL (US)

(21) Appl. No.: 18/909,107

(22) Filed: Oct. 8, 2024

Related U.S. Application Data
(60) Provisional application No. 63/588,813, filed on Oct. 9, 2023.

(51) Int. Cl. H05K 5/02

(52) U.S. Cl. CPC H05K 5/0295

(57) ABSTRACT

A handle system for ejecting a cartridge including (1) a cartridge housing, (2) a first elongate member having a first end and an opposing second end, and (3) a first lever arm secured to the first end of the first elongate member to form a ninety-degree angle therewith, wherein the second end of the first elongate member may be pivotally connected to the cartridge housing.

### RELATED APPLICATIONS

This application claims priority under 35 U.S.C. § 119 (e) of U.S. Provisional Patent Application Ser. No. 63/588,813 (Attorney Docket No. 7687.00004) filed on Oct. 9, 2023 and titled EJECTOR HANDLES. The content of this application is incorporated herein by reference.

### FIELD OF THE INVENTION

The present invention relates to systems and methods for decoupling cartridges from other systems. In particular, the present invention provides a handle that a user may utilize to physically remove a cartridge from a coupled system.

### BACKGROUND OF THE INVENTION

Cartridges may be physically secured to systems by contacts made through electrical connectors. Particularly in systems with many pins included in the electrical connector, these systems may be difficult to decouple. Therefore, a need exists in the art for a handle system that may provide a user with a way to obtain better leverage or a better physical grip on the cartridge to aid in decoupling the cartridge from a connected system.

This background information is provided to reveal information believed by the applicant to be of possible relevance to the present invention. No admission is necessarily intended, nor should be construed, that any of the preceding information constitutes prior art against the present invention.

### SUMMARY OF THE INVENTION

With the above in mind, embodiments of the present invention are related to a handle system for ejecting a cartridge including a cartridge housing, a first elongate member, and a first lever arm.

The first elongate member may have a first end and an opposing second end.

The first lever arm may be secured to the first end of the first elongate member to form a ninety-degree angle therewith.

The second end of the first elongate member may be pivotally connected to the cartridge housing.

The first lever arm may be located on a first end of the cartridge housing and the cartridge housing may include an electrical connector located on a second end of the cartridge housing, which opposes the first end of the cartridge housing.

An outer edge of the first elongate member may be arcuate and concave.

The handle system may also include a second elongate member and a second lever arm.

The second elongate member may have a first end and an opposing second end.

The second lever arm may be secured to the first end of the second elongate member to form a ninety-degree angle therewith.

The second end of the second elongate member may be pivotally connected to the cartridge housing.

An outer edge of the second elongate member may be arcuate and concave.

The cartridge housing may have a first side and an opposing second side. The first lever arm may be pivotally secured at the first side of the cartridge housing and the second lever arm may be pivotally secured at the second side of the cartridge housing.

The first lever arm may be adapted to pivot independently of the second lever arm.

The handle system for ejecting a cartridge may include a cartridge, a first elongate member, a first lever arm, a second elongate member, and a second lever arm. The cartridge housing may have a first side and an opposing second side. The first elongate member may have a first end and an opposing second end. The first lever arm may be secured to the first end of the first elongate member to form a ninety-degree angle therewith. The second elongate member may have a first end and an opposing second end. The second lever arm may be secured to the first end of the second elongate member to form a ninety-degree angle therewith. The second end of the first elongate member may be pivotally connected to the first side of the cartridge housing and the second end of the second elongate member may be pivotally connected to the second side of the cartridge housing.

The first lever arm may be adapted to pivot independently of the second lever arm.

The first lever arm may be adapted to pivot in tandem with the second lever arm.

An outer edge of the first elongate member may be arcuate and concave and an outer edge of the second elongate member may be arcuate and concave.

The handle system for ejecting a cartridge may include a cartridge housing a first elongate member, a first lever arm, a second elongate member, a second lever arm, and a coupler. The cartridge housing may have a first side and an opposing second side. The first elongate member may have a first end and an opposing second end. The first lever arm may be secured to the first end of the first elongate member to form a ninety-degree angle therewith. The second elongate member may have a first end and an opposing second end. The second lever arm may be secured to the first end of the second elongate member to form a ninety-degree angle therewith. The coupler may be connected to the first lever arm and the second lever arm. The second end of the first elongate member may be pivotally connected to the first side of the cartridge housing and the second end of the second elongate member may be pivotally connected to the second side of the cartridge housing. Changing the distance between the coupler and the cartridge housing may cause the first lever arm to pivot, with respect to the cartridge housing, in tandem with the second lever arm.

The handle system may also include a first coupling member and a second coupling member.

The first coupling member may have a first end and an opposing second end. The second end may be pivotally secured to the first side of the cartridge housing.

The second coupling member may have a first end and an opposing second end. The second end may be pivotally secured to the second side of the cartridge housing.

The coupler may include a first elongate aperture and a second elongate aperture.

The first end of the first coupling member may be captured by the first elongate aperture. The first end of the second coupling member may be captured by the second elongate aperture.

The coupler may be positionable between a retracted and an extended position. In the retracted position, the first coupling member may be parallel to the first elongate aperture and the second coupling member may be parallel to the second elongate aperture. In the extended position, the first coupling member may not be parallel to the first elongate aperture and the second coupling member may not be parallel to the second elongate aperture.

The first elongate aperture may have a first end and an opposing second end. The second elongate aperture may have a first end and an opposing second end.

In the retracted position, the first end of the first coupling member may be located at a first end of the first elongate aperture and the first end of the second coupling member may be located at a first end of the second elongate aperture.

In the extended position, the first end of the first coupling member may be located at a second end of the first elongate aperture and the first end of the second coupling member may be located at a second end of the second elongate aperture.

The second end of the first lever arm may be connected to the second end of the first coupling member such that pivoting the first coupling member with respect to the cartridge housing causes the first lever arm to pivot with respect to the cartridge housing.

The second end of the second lever arm may be connected to the second end of the second coupling member such that pivoting the second coupling member with respect to the cartridge housing causes the second lever arm to pivot with respect to the cartridge housing.

The coupler may be positionable between a retracted position, wherein the coupler is proximate the cartridge housing, and an extended position, wherein the coupler is moved away from the cartridge housing. Transitioning the coupler from the retracted position to the extended position may cause the first coupling member and the second coupling member to pivot with respect to the cartridge housing.

### BRIEF DESCRIPTION OF THE DRAWINGS

Some embodiments of the present invention are illustrated as an example and are not limited by the figures of the accompanying drawings, in which like references may indicate similar elements.

FIG. 1 is a perspective view of the ejector handles in an inserted and locked position according to one embodiment of the present invention.

FIG. 2 is a perspective view of the ejector handles of FIG. 1 in an unlocked and removed position.

FIG. 3 is a perspective view of the ejector handles in an inserted and locked position according to another embodiment of the present invention.

FIG. 4 is a perspective view of the ejector handles of FIG. 3 in an unlocked and removed position.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Those of ordinary skill in the art realize that the following descriptions of the embodiments of the present invention are illustrative and are not intended to be limiting in any way. Other embodiments of the present invention will readily suggest themselves to such skilled persons having the benefit of this disclosure. Like numbers refer to like elements throughout.

Although the following detailed description contains many specifics for the purposes of illustration, anyone of ordinary skill in the art will appreciate that many variations and alterations to the following details are within the scope of the invention. Accordingly, the following embodiments of the invention are set forth without any loss of generality to, and without imposing limitations upon, the claimed invention.

In this detailed description of the present invention, a person skilled in the art should note that directional terms, such as “above,” “below,” “upper,” “lower,” and other like terms are used for the convenience of the reader in reference to the drawings. Also, a person skilled in the art should notice this description may contain other terminology to convey position, orientation, and direction without departing from the principles of the present invention.

Furthermore, in this detailed description, a person skilled in the art should note that quantitative qualifying terms such as “generally,” “substantially,” “mostly,” and other terms are used, in general, to mean that the referred to object, characteristic, or quality constitutes a majority of the subject of the reference. The meaning of any of these terms is dependent upon the context within which it is used, and the meaning may be expressly modified.

An embodiment of the invention, as shown and described by the various figures and accompanying text, provides a

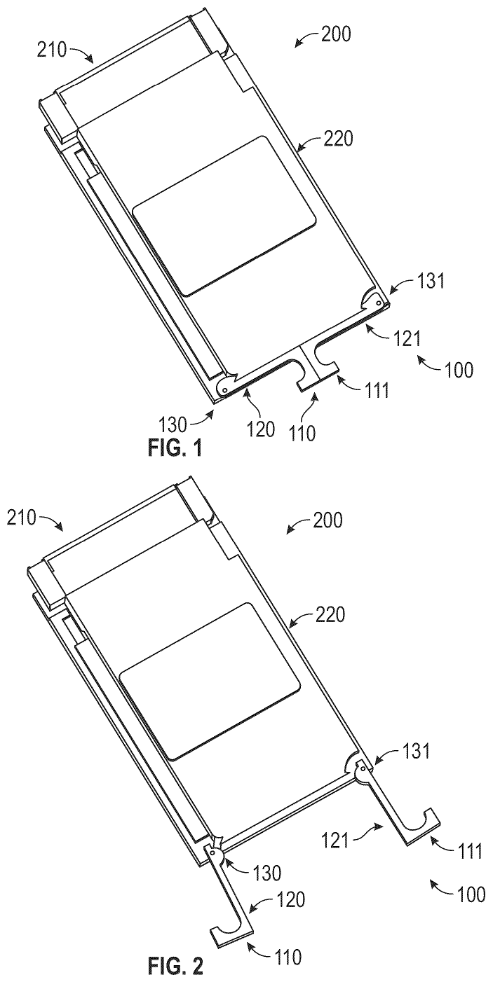

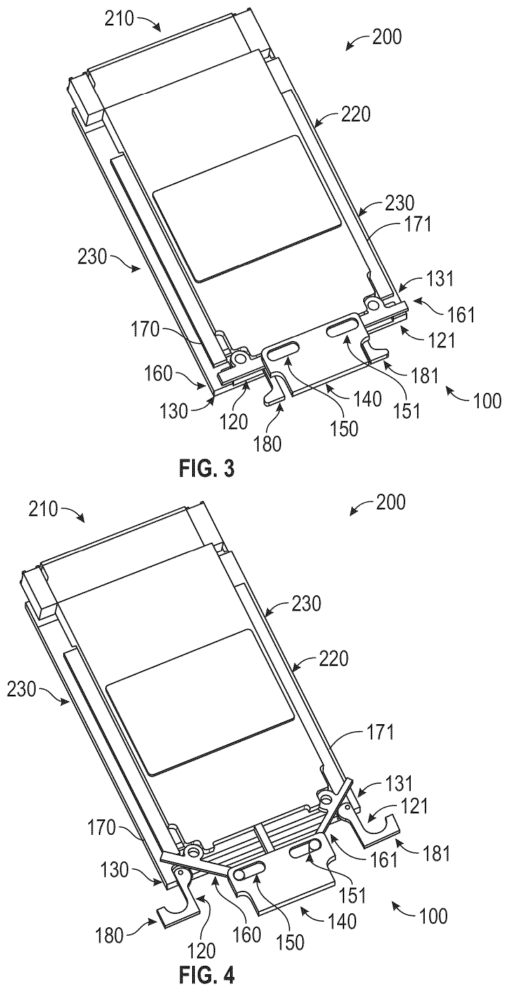

An embodiment of the invention, as shown and described by the various figures and accompanying text, provides a handle system 100 secured to a cartridge housing 220. The cartridge housing 220 may be part of a cartridge 200 that provides external memory for rugged flight computers. The handle system 100 may be configured to remove and insert the cartridge 200 with a VPX connector 210. The handle system 100 may include wedge-lock handles 110, 111, as depicted at least in FIGS. 1 & 2, to add leverage to a user when removing a cartridge 200. In one embodiment, at least as depicted in FIGS. 3 & 4, the handle system 100 may provide a solution to engage two ejectors/injectors 230 secured to a single cartridge 200 with one motion. The handle system 100 may be secured to a cartridge housing 220 at an end opposing the location of the VPX connector 210.

Turning to FIG. 1, according to one embodiment of the invention, the handle system 100 may include a first wedge-lock handle 110 secured to a first end of a first lever arm 120. A second end of the first lever arm 120 may be secured to a first pivot 130. When in the inserted and locked position, applying pressure to the first wedge-lock handle 110 in a direction opposite the location of the cartridge housing 220 may cause the first lever arm 120 to rotate about the first pivot 130 from the inserted and locked position, as depicted in FIG. 1, to an unlocked and removed position, as depicted in FIG. 2. When in the unlocked and removed position, applying pressure to the first wedge-lock handle 110 in a direction of the location of the cartridge housing 220 may cause the first lever arm 120 to rotate about the first pivot 130 from the unlocked and removed position, as depicted in FIG. 2, to an inserted and locked position, as depicted in FIG. 1.

The first wedge-lock handle 110 may include an elongate member that forms a 90-degree angle with the first lever arm 120. An outer edge of the elongate member of the first wedge-lock handle 110 may be arcuate and concave to provide a more ergonomic experience for the user.

The handle system 100 may also include a second wedge-lock handle 111 secured to a first end of a second lever arm 121. A second end of the second lever arm 121 may be secured to a second pivot 131. The first pivot 130 and second pivot 131 may be located at opposing front corners of the cartridge housing 220. When in the inserted and locked position, applying pressure to the second wedge-lock handle 111 in a direction opposite the location of the cartridge housing 220 may cause the second lever arm 121 to rotate about the second pivot 131 from the inserted and locked position, as depicted in FIG. 1, to an unlocked and removed position, as depicted in FIG. 2. When in the unlocked and removed position, applying pressure to the second wedge-lock handle 111 in a direction of the location of the cartridge housing 220 may cause the second lever arm 121 to rotate about the second pivot 131 from the unlocked and removed position, as depicted in FIG. 2, to an inserted and locked position, as depicted in FIG. 1.

The first wedge-lock handle 110 may form a 90-degree angle with the first lever arm 120. An outer edge of the first wedge-lock handle 110 may be arcuate and concave to provide a more ergonomic experience for the user. Similarly, the second wedge-lock handle 111 may form a 90-degree angle with the second lever arm 121. An outer edge of the second wedge-lock handle 111 may be arcuate and concave to provide a more ergonomic experience for the user.

In an embodiment as depicted in FIGS. 1 & 2, the first lever arm 120 and second lever arm 121 may be move independently of each other. An inner edge of the first wedge-lock handle 110 may be straight and lie flush against an inner edge of the second wedge-lock handle 111, which may also be straight, when both the first wedge-lock handle 110 and the second wedge-lock handle 111 are in the inserted and locked position.

Turning to FIGS. 3 & 4, an alternate embodiment of the handle 100 is provided. In this embodiment, the first lever arm 120 and second lever arm 121 move in tandem with one another. The embodiment depicted in FIGS. 3 & 4 may have a first wedge-lock handle 180 and a second wedge-lock handle 181. The first wedge-lock handle 180 may form a 90-degree angle with the first lever arm 120. An outer edge of the first wedge-lock handle 110 may be arcuate and concave to provide a more ergonomic experience for the user. Similarly, the second wedge-lock handle 181 may form a 90-degree angle with the second lever arm 121. An outer edge of the second wedge-lock handle 181 may be arcuate and concave to provide a more ergonomic experience for the user. The first lever arm 120 and second lever arm 121 of the embodiment depicted in FIGS. 3 and 4 may be shorter than the first lever arm 120 and second lever arm 121 of the embodiment depicted in FIGS. 1 and 2.

This embodiment of the handle 100 may include a coupler 140. The coupler 140 may be vertically symmetrical with a first side identical to a second side. The coupler 140 may include a first elongate aperture 150 on the first side and a second elongate aperture 151 on the second side. A first end of a first coupling member 160 may be carried by the first elongate aperture 150. The first end of the first coupling member 160 may be configured to slide between a first side and a second side of the first elongate aperture 150. Similarly, a first end of a second coupling member 161 may be carried by the second elongate aperture 151. The first end of the second coupling member 161 may be configured to slide between a first side and a second side of the second elongate aperture 151.

When in the inserted and locked position, the coupler 140 may be adjacent the cartridge housing 220, the first end of the first coupling member 160 may be adjacent a second side of the first elongate aperture 150, the first coupling member 160 may be parallel to the first elongate aperture 150, the first end of the second coupling member 161 may be adjacent a first side of the second elongate aperture 151, and the second coupling member 161 may be parallel to the second elongate aperture 151.

A second end of the first coupling member 160 may be secured to a first coupling pivot 170. When moved from the inserted and locked position to the unlocked and removed position, a user may exert pressure on the coupler 140 in a direction opposing the cartridge housing 220. This may cause the coupler 140 to move away from the cartridge housing 220, causing the first end of the first coupling member 160 to slide from the second side of the first elongate aperture 150 toward the first side of the first elongate aperture 150 and causing the first coupling member 160 to pivot about the first coupling pivot 170.

Similarly, a second end of the second coupling member 161 may be secured to a second coupling pivot 171. When moved from the inserted and locked position to the unlocked and removed position, the first end of the second coupling member 161 may slide from the first side of the second elongate aperture 151 toward the second side of the second elongate aperture 151 and cause the second coupling member 161 to pivot about the second coupling pivot 171.

The rotation of the first coupling member 160 about the first coupling pivot 170 and the second coupling member 161 about the second coupling pivot 171 may exert a rotational force on both the first pivot 130 and second pivot 131. As first coupling member 160 moves about first pivot 130, first coupling member 160 may exert pressure on a first protrusion extending from the housing 220 beneath the path of first coupling member 160. This force on the first protrusion may disengage the first lever arm 120. Similarly, as second coupling member 161 moves about second pivot 131, second coupling member 161 may exert pressure on a second protrusion extending from the housing 220 beneath the path of second coupling member 161. This force on the second protrusion may disengage the second lever arm 121. When disengaged, the first lever arm 120 and second lever arm 121 may move from the inserted and locked position, as depicted in FIG. 3, to the unlocked and removed position, as depicted in FIG. 4.

Some of the illustrative aspects of the present invention may be advantageous in solving the problems herein described and other problems not discussed which are discoverable by a skilled artisan.

While the above description contains much specificity, these should not be construed as limitations on the scope of any embodiment, but as exemplifications of the presented embodiments thereof. Many other ramifications and variations are possible within the teachings of the various embodiments. While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best or only mode contemplated for carrying out this invention, but that the invention will include all embodiments falling within the scope of the appended claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

Thus the scope of the invention should be determined by the appended claims and their legal equivalents, and not by the examples given.

What is claimed is:

1. A handle system for ejecting a cartridge comprising:
a cartridge housing;
a first elongate member having a first end and an opposing second end; and
a first lever arm secured to the first end of the first elongate member to form a ninety-degree angle therewith; and
wherein the second end of the first elongate member is pivotally connected to the cartridge housing.

2. The handle system of claim 1 wherein the first lever arm is located on a first end of the cartridge housing and the cartridge housing further comprises an electrical connector located on a second end of the cartridge housing, which opposes the first end of the cartridge housing.

3. The handle system of claim 1 wherein an outer edge of the first elongate member is arcuate and concave.

4. The handle system of claim 1 further comprising:
a second elongate member having a first end and an opposing second end; and
a second lever arm secured to the first end of the second elongate member to form a ninety-degree angle therewith; and
wherein the second end of the second elongate member is pivotally connected to the cartridge housing.

5. The handle system of claim 4 wherein an outer edge of the second elongate member is arcuate and concave.

6. The handle system of claim 4 wherein the cartridge housing has a first side and an opposing second side and wherein the first lever arm is pivotally secured at the first side of the cartridge housing and the second lever arm is pivotally secured at the second side of the cartridge housing.

7. The handle system of claim 4 wherein the first lever arm is adapted to pivot independently of the second lever arm.

8. A handle system for ejecting a cartridge comprising:
a cartridge housing having a first side and an opposing second side;
a first elongate member having a first end and an opposing second end;
a first lever arm secured to the first end of the first elongate member to form a ninety-degree angle therewith;
a second elongate member having a first end and an opposing second end; and
a second lever arm secured to the first end of the second elongate member to form a ninety-degree angle therewith; and
wherein the second end of the first elongate member is pivotally connected to the first side of the cartridge housing and the second end of the second elongate member is pivotally connected to the second side of the cartridge housing.

9. The handle system of claim 8 wherein the first lever arm is adapted to pivot independently of the second lever arm.

10. The handle system of claim 8 wherein the first lever arm is adapted to pivot in tandem with the second lever arm.

11. The handle system of claim 8 wherein an outer edge of the first elongate member is arcuate and concave and an outer edge of the second elongate member is arcuate and concave.

12. A handle system for ejecting a cartridge comprising:
a cartridge housing having a first side and an opposing second side;
a first elongate member having a first end and an opposing second end;
a first lever arm secured to the first end of the first elongate member to form a ninety-degree angle therewith;
a second elongate member having a first end and an opposing second end;
a second lever arm secured to the first end of the second elongate member to form a ninety-degree angle therewith; and
a coupler connected to the first lever arm and the second lever arm;
wherein the second end of the first elongate member is pivotally connected to the first side of the cartridge housing and the second end of the second elongate member is pivotally connected to the second side of the cartridge housing; and
wherein changing the distance between the coupler and the cartridge housing causes the first lever arm to pivot, with respect to the cartridge housing, in tandem with the second lever arm.

13. The handle system of claim 12 further comprising:
a first coupling member having a first end and an opposing second end, wherein the second end is pivotally secured to the first side of the cartridge housing; and
a second coupling member having a first end and an opposing second end, wherein the second end is pivotally secured to the second side of the cartridge housing.

14. The handle system of claim 13 wherein the coupler further comprises:
a first elongate aperture; and
a second elongate aperture;
wherein the first end of the first coupling member is captured by the first elongate aperture; and
wherein the first end of the second coupling member is captured by the second elongate aperture.

15. The handle system of claim 14 wherein the coupler may be positionable between a retracted and an extended position;
wherein in the retracted position, the first coupling member is parallel to the first elongate aperture and the second coupling member is parallel to the second elongate aperture; and
wherein in the extended position, the first coupling member is not parallel to the first elongate aperture and the second coupling member is not parallel to the second elongate aperture.

16. The handle system of claim 15 wherein the first elongate aperture has a first end and an opposing second end;
wherein the second elongate aperture has a first end and an opposing second end;
wherein in the retracted position, the first end of the first coupling member is located at a first end of the first elongate aperture and the first end of the second coupling member is located at a first end of the second elongate aperture; and
wherein in the extended position, the first end of the first coupling member is located at a second end of the first elongate aperture and the first end of the second coupling member is located at a second end of the second elongate aperture.

17. The handle system of claim 13 wherein the second end of the first lever arm is connected to the second end of the first coupling member such that pivoting the first coupling member with respect to the cartridge housing causes the first lever arm to pivot with respect to the cartridge housing.

18. The handle system of claim 17 wherein the second end of the second lever arm is connected to the second end of the second coupling member such that pivoting the second coupling member with respect to the cartridge housing causes the second lever arm to pivot with respect to the cartridge housing.

19. The handle system of claim 18 wherein the coupler may be positionable between a retracted position, wherein the coupler is proximate the cartridge housing, and an extended position, wherein the coupler is moved away from the cartridge housing; and
wherein transitioning the coupler from the retracted position to the extended position causes the first coupling member and the second coupling member to pivot with respect to the cartridge housing.
